(19) United States
(12) Patent Application Publication
(10) Pub. No.: US 2007/0145496 A1
(43) Pub. Date: Jun. 28, 2007

(54) SEMICONDUCTOR DEVICE AND METHOD OF MANUFACTURING THE SAME

(76) Inventor: Eun Jong Shin, Seoul (KR)

Correspondence Address: SHERR & NOURSE, PLLC, 620 HERNDON PARKWAY, SUITE 200, HERNDON, VA, 20170, US

(21) Appl. No.: 11/609,888

(22) Filed: Dec. 12, 2006

(30) Foreign Application Priority Data
Dec. 28, 2005 (KR) 10-2005-0131557

(51) Int. Cl. H01L 29/76

(52) U.S. Cl. 257/408

(57) ABSTRACT

according to embodiments, a semiconductor device may include a semiconductor substrate in which source and drain regions may be formed, a gate insulating layer formed on the semiconductor substrate, a gate electrode formed on the gate insulating layer, a first sidewall insulating layer formed on the side of the gate electrode, a third sidewall insulating layer formed on the side of the first sidewall insulating layer, and a second sidewall insulating layer formed between the first sidewall insulating layer and the third sidewall insulating layer.

The present application claims priority under 35 U.S.C. 119 and 35 U.S.C. 365 to Korean Patent Application No. 10-2005-0131557 (filed on Dec. 28, 2005), which is hereby incorporated by reference in its entirety.

### BACKGROUND

As applications of highly integrated CMOS devices having a line width of 90 nm or less have accelerated, focus has been placed upon process integration issues in an attempt to obtain high-speed operation of devices.

CMOS devices may have a line width of 90 nm or less. Related art high-integration technologies, such as high-density SRAM (4-Transistor or 6-Transistor) and pseudo SRAM (1-Transistor), may be used to achieve these line widths.

Process integration issues may include steep retrograde well formation, strained silicon substrates, ultra shallow junction formation, gate conductor patterning issue in ArF litho and other sources, and shallow trench isolation/gate etching processes.

Such process integration issues may be important process parameters that directly effect transistor performance. Thus, research and development have been conducted on the process integration issues by various researchers and laboratories to identify optimal process conditions.

Hereinafter, a method of manufacturing a related art semiconductor device will be described with reference to the attached drawings.

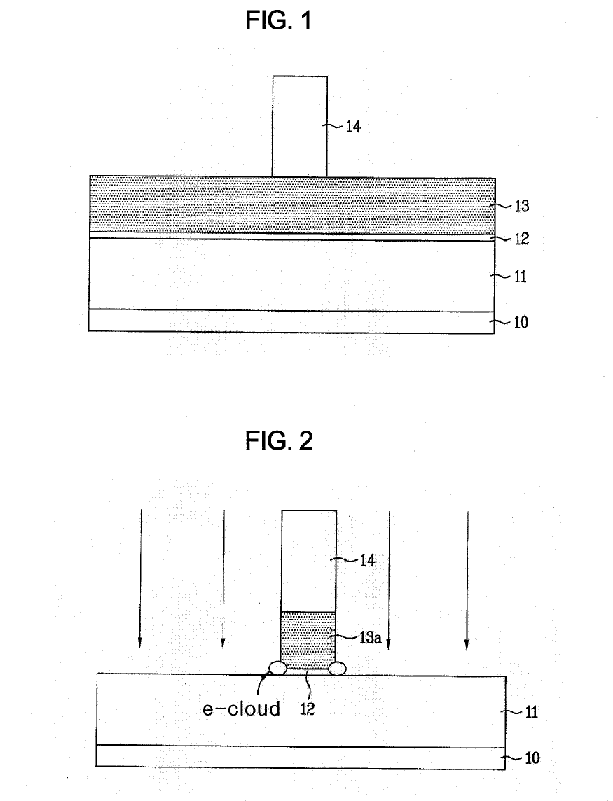

Referring to FIG. 1, well 11 may be formed, for example by implanting impurity ions into substrate 10. A cleaning process may be performed using diluted HF. Well 11 may control a channel stop and a threshold voltage (Vt).

Gate insulating layer 12 may have a thickness of about 20 Å to 40 Å. Gate insulating layer 12 may be formed on substrate 10. Polysilicon layer 13, which may having a thickness of about 2,000 Å to 2,200 Å, may be deposited on gate insulating layer 12, for example through a low pressure chemical vapor deposition (LPCVD) method.

Polysilicon layer 13 may be coated with a photosensitive layer 14. Photosensitive layer 14 may be selectively patterned, for example by exposure and development processes. Photosensitive layer 14 may be patterned by an ArF or KrF lithography method to have a line width of 90 nm or less.

Referring to FIG. 2, polysilicon layer 13 may be etched using patterned photosensitive layer 14 as a mask, and may form gate electrode 13a.

Polysilicon layer 13 may be etched, for example by a reactive ion etch (RIE) method using a high density plasma source of inductively coupled plasma (ICP).

If polysilicon layer 13 is etched as described above, ions incident in a plasma state may be scattered and trajectory deflected due to electrons, ion charging effect, and electron cloud that are generated during an etching process.

Therefore, the ends of the sidewalls and the bottom of gate electrode 13a may be tapered.

As a result, a notching phenomenon may be generated on a bottom of gate electrode 13a. A depth and height of the notching may be irregularly controlled in accordance with the plasma characteristic of an etching chamber. Transistor performance may therefore significantly change.

For reference, the gate notching phenomenon generated in the conventional art can be affected by pressure, temperature, and radio frequency (RF) power in a chamber during the RIE process.

The gate notching phenomenon may be severe in a pattern where a line width of the gate electrode is shrunken and width/space margins are dense. Such a process issue may occur more frequently in a cell where the design issue is important, for example such as the high density SRAM.

Therefore, in the gate to gate space of the integrated patterns, the ion deflection and ion scattering that are caused by the electron charging dominantly affects the gate notching phenomenon.

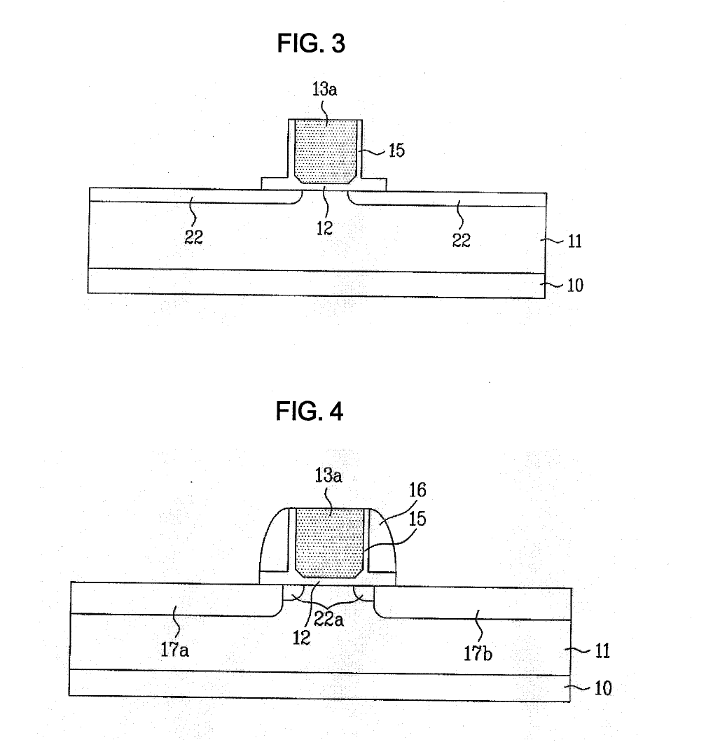

Referring to FIG. 3, first sidewall insulating layer 15 may be formed on the sidewalls of gate electrode 13a, for example by an oxidation process.

A pocket (halo) ion implantation process may improve short channel effect (SCE). To perform the pocket (halo) ion implementation process, low density impurity ions may be implanted into substrate 10 on both sides of gate electrode 13a and may form low density ion implantation regions 22.

Due to the notching phenomenon on the bottom of gate electrode 13a, optimal pocket (halo) ion implantation may be available.

However, during the oxidation process of forming the first sidewall insulating layer 15, a re-oxidation rate may increase in the notching region due to the notching phenomenon. This may cause a thickness of gate oxide layer 12 at the bottom edge of gate electrode 13a to increases. I_{off} may also increase due to an oxidation enhanced diffusion (OED) phenomenon. The threshold voltage Vt may also increase (Iₒₙ is reduced) due to fringing effect.

Referring to FIG. 4, a SiN layer may be deposited on an entire surface of substrate 10 including gate electrode 13a. Blanking etching may then be performed to form second sidewall insulating layer 16 on the sidewalls of gate electrode 13a including the first sidewall insulating layer 15.

Ions may be implanted into substrate 10 including gate electrode 13a and may form source and drain regions 17a and 17b. Since the overlap margins of gate electrode 13a and source and drain regions 17a and 17b may be reduced due to the notching phenomenon at the bottom edge of gate electrode 13a, gate induced drain leakage (GIDL) may therefore be reduced. Device performance, however, may be degraded due to the increase of the threshold voltage Vt (the reduction in the on current Iₒₙ).

As a result, lightly doped drain (LDD) region 22a may be formed in low density ion implantation region 22 formed below gate electrode 13a.

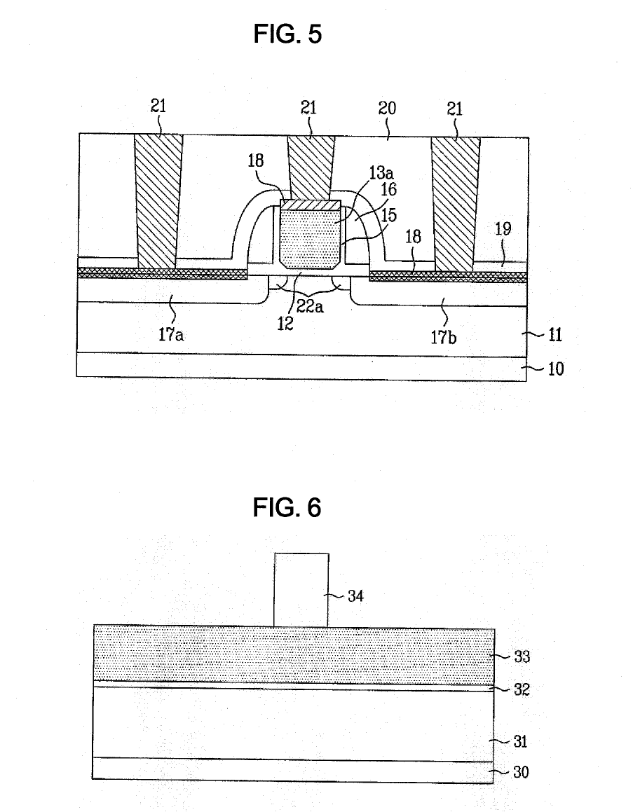

Referring to FIG. 5, a metal layer may be deposited on an entire surface of substrate 10 including gate electrode 13a. A rapid annealing process may then be performed, and may form salicide layers 18 on surfaces of source and drain regions 17a and 17b and gate electrode 13a. If cobalt is used as a metal, the salicide layers 18 may be cobalt salicide layers.

Etch stop layers 19 and interlayer insulating layer 20 may then be deposited on an entire surface of substrate 10. Contact holes may be formed, for example by a photolithography process and may expose source and drain regions 17a and 17b and gate electrode 13a. Tungsten may be deposited on an entire surface of the interlayer insulating layer including the contact holes. Contact plugs 21 may then be formed and the tungsten may be left in the contact holes.

The above described method of manufacturing a related semiconductor device may have various problems. For example, a thickness of a gate insulating layer may increase due to the re-oxidation caused by the gate notching phenomenon and may cause a fringing effect. This may increase a threshold voltage Vt and reduce the on current Iₒₙ. As a result, transistor performance may be degraded.

### SUMMARY

Embodiments relate to a semiconductor device. Embodiments relate to a structure of a semiconductor device and a method of manufacturing the same.

Embodiments relate to a highly integrated transistor capable of minimizing device performance degradation.

According to embodiments, a semiconductor device may include a semiconductor substrate in which source and drain regions are formed, a gate insulating layer formed on the semiconductor substrate, a gate electrode formed on the gate insulating layer, a first sidewall insulating layer formed on the side of the gate electrode, a third sidewall insulating layer formed on the side of the first sidewall insulating layer, and a second sidewall insulating layer formed between the first sidewall insulating layer and the third sidewall insulating layer.

According to embodiments, a method of manufacturing a semiconductor device may include sequentially forming a gate insulating layer and a gate electrode on a semiconductor substrate, forming a first sidewall insulating layer on the side of the gate electrode, forming a second sidewall insulating layer having a notched structure on the side of the first sidewall insulating layer, forming a third sidewall insulating layer on the side of the second sidewall insulating layer, and implanting impurity ions using the third sidewall insulating layer as an ion implantation mask to form source and drain regions in the semiconductor substrate.

### BRIEF DESCRIPTION OF THE DRAWINGS

Example FIGS. 1 to 5 are drawings that illustrate a related semiconductor device and a method of manufacturing the same; and

Example FIGS. 6 to 11 are drawings that illustrate a semiconductor device and a method of forming a semiconductor device according to embodiments.

### DETAILED DESCRIPTION OF EMBODIMENTS

Embodiments may be applied to a deep sub-micron CMOS device having a line width of 90 nm or less. Embodiments may be applied to a pattern in which gate electrodes are integrated.

According to embodiments, a transistor and a method of manufacturing the same will be described.

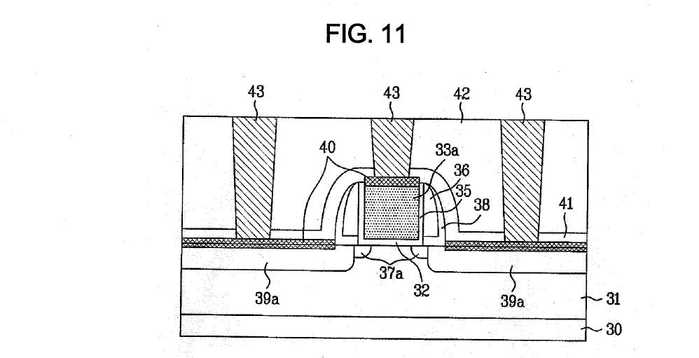

Referring to FIG. 11, according to embodiments, retrograde well 31 that may be doped with a first conductor may be formed in substrate 30. Gate insulating layer 32 and gate electrode 33a may be formed on substrate 30.

First sidewall insulating layer 35 may be formed on both sides of gate electrode 33a. Second sidewall insulating layer 36, which may be separated from substrate 30 by a predetermined distance, may be formed on the sides of first sidewall insulating layer 35.

An end of first sidewall insulating layer 35 and an end of gate insulating layer 32 may be connected to each other.

Second sidewall insulating layer 36, which may be separated from substrate 30 by the predetermined distance, may be referred to as sidewall notching.

Third sidewall insulating layer 38 may be formed on the sides of second sidewall insulating layer 36. Third sidewall insulating layer 38 may be formed under second sidewall insulating layer 36.

In other words, a part of third sidewall insulating layer 38 may separate first sidewall insulating layer 35 and the semiconductor substrate 30 from each other.

LDD region 37a may be formed on both sides of substrate 30 under gate electrode 33a. Source and drain regions 39a and 39b may be formed on both sides of substrate 30. Source and drain regions 39a and 39b may not be formed under gate electrode 33a.

Salicide layers 40 may be formed on a top surface of each of source drain regions 39a and 39b and gate electrode 33a.

Etch stop layers 41 may be formed on source and drain regions 39a and 39b and gate electrode 33a. Interlayer insulating layers 42 may be formed on etch stop layers 41.

Contact holes may be formed in etch stop layers 41 and interlayer insulating layers 42. Contact plugs 43, for example in which a conductor may be buried, may be formed in the contact holes.

A method of manufacturing a semiconductor device according to embodiments will be described.

Referring to FIG. 6, a first conductive type ion may be implanted into substrate 30 and may form retrograde well 31. A cleaning process may be performed by HF. Retrograde well 31 may control a channel stop and a threshold voltage Vt.

Gate insulating layer 32, for example having a thickness of approximately 20 to 40 Å, may be formed on substrate 30. Polysilicon layer 33, for example having a thickness of approximately 2,000 to 2,200 Å, may be deposited on gate insulating layer 32, for example by a low pressure chemical vapor deposition (LPCVD) method.

Polysilicon layer 33 may be coated with photosensitive layer 34. Photosensitive layer 34 may then be selectively patterned by exposure and development processes. According to embodiments, photosensitive layer 34 may be patterned, for example using an ArF or KrF lithography method, and may have a line width of 90 nm or smaller than 90 nm.

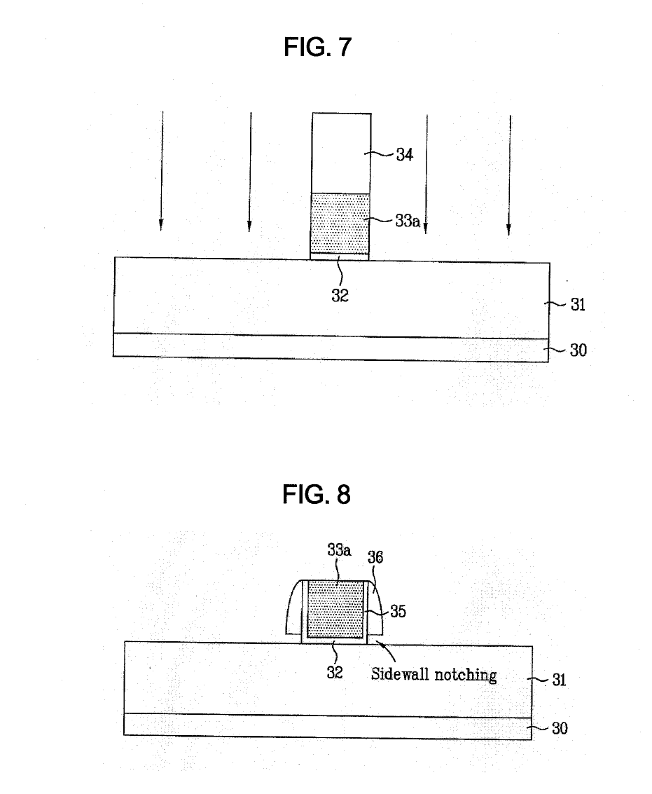

Referring to FIG. 7, polysilicon layer 33 may be etched, for example using patterned polysilicon layer 34 as mask to form gate electrode 13a.

Polysilicon layer 33 may be etched, for example by a reactive ion etch (RIE) method using a high density plasma source of inductively coupled plasma (ICP) under low pressure of about 40 to 60 mTorr.

To improve or avoid a gate notching phenomenon, according to embodiments, an RIE process may be performed under as low a pressure as possible. This may improve the gate notching phenomenon caused by the field deflection generated by the electron charging.

Also, it may be necessary to optimize the poor reactive ion etching effect caused the low pressure.

Referring to FIG. 8, first sidewall insulating layer 35 may be formed on sidewalls of gate electrode 33a, for example by an oxidation process.

An SiN layer or a tetra ethyl ortho silicate (TEOS) layer may be deposited by the LPCVD method and second sidewall insulating layer 36 may be formed on a side of first sidewall insulating layer 35, for example by a self align blanket etching method.

Second sidewall insulating layer 36 may function as a buffer spacer in order to improve the GIDL characteristic.

According to embodiments, to facilitate an optimal pocket ion implantation process that may improve the SCE, a bottom of second side insulating layer 36 connected to substrate 30 may be removed through a diluted HF cleaning.

According to embodiments, a bottom of second sidewall insulating layer 36 may be partially removed to perform sidewall notching.

According to embodiments, it may be possible to correctly control a depth and height of the sidewall notching. The sidewall notching may be performed as described above so that, during a subsequent inclination pocket ion implantation process, it may be possible to realize and optimal pocket ion implantation and to thus effectively improve the SCE.

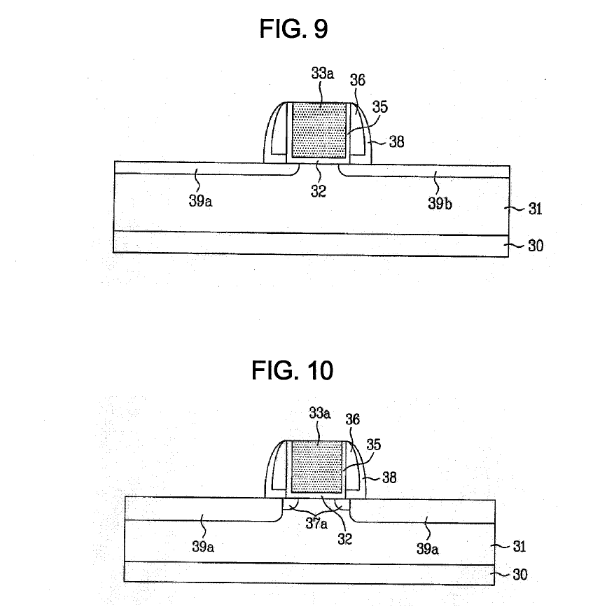

Referring to FIG. 9, low density ion implantation regions may be formed in substrate 30 on both sides of gate electrode 33a. Low-density ion implantation regions may be formed through a high current ion implantation process and an inclination current ion implantation process. The ion implantation may be referred to as the pocket ion implantation process.

In embodiments, it may be possible to form an optimal pocket profile due to the sidewall notched structure in which a bottom of second sidewall insulating layer 36 is removed.

An insulating layer may be deposited on a surface (or the entire surface) of substrate 30 including gate electrode 33a, for example by a low pressure chemical vapor deposition (LPCVD) method. The blanket etching may then be performed to form third sidewall insulating layer 38 on the sidewalls of the second sidewall insulating layer.

Referring to FIG. 10, a high current ion implantation process may be performed, and may form source and drain regions 39a and 39b in substrate 30 on both sides of gate electrode 33a.

At this time, since overlap margins between gate electrode 33a and source region 39a and between gate electrode 33a and drain region 39b may be reduced due to the sidewall notched structure in which the bottom of second sidewall insulating layer 36 is removed, it may be advantageous to the GIDL.

Also, it may be possible to prevent the threshold voltage Vt from increasing (the on current Iₒₙ from being reduced) due to a gate fringing effect caused by the re-oxidation phenomenon of the related art notching gate structure.

LLD regions 37a may be formed in substrate 30 on both sides under gate electrode 33a.

Referring to FIG. 11, a metal layer may be deposited on a surface (for example the entire surface) of substrate 30 including gate electrode 33a. A rapid annealing process may then be performed to form salicide layers 40 on surfaces of source and drain regions 39a and 39b and gate electrode 33a.

In embodiments, when cobalt is used as a metal, the salicide layers 40 may be cobalt salicide layers.

Etch stop layers 41 and interlayer insulating layer 42 may be deposited on substrate 30. Contact holes may be formed by a photolithography process to expose source and drain regions 39a and 39b and gate electrode 33a. Tungsten may be deposited on a surface (for example the entire surface) of interlayer insulating layer 42 including the contact holes. Contact plugs 43 may be formed, and the tungsten may be left in the contact holes.

According to embodiments, since the semiconductor device may be manufactured so that the bottom of second sidewall insulating layer 36 may have the sidewall notched structure, it may be possible to prevent a thickness of the gate insulating layer from increasing due to the re-oxidation that may be caused by the related art gate notching phenomenon.

According to embodiments, since the semiconductor device may be manufactured so that the bottom of second sidewall insulating layer 36 has the sidewall notched structure, it may be possible to prevent the off current I_{off} of a PMOS transistor from increasing due to the oxidation enhanced boron diffusion (OED) that may be caused by the increase in the thickness of the gate edge, that is, at a bottom of the gate insulating layer.

According to embodiments, it may be possible to use the semiconductor device in highly integrated devices of less than 90 nm having high speed operation and low leakage current.

According to embodiments, since the semiconductor device may be manufactured so that the bottom of second sidewall insulating layer 36 has the sidewall notched structure, it may be possible to form the optimal pocket ion implantation region so that problems caused by the SCE may be improved.

According to embodiments, since the semiconductor device may be manufactured so that the bottom of second sidewall insulating layer 36 has the sidewall notched structure, the overlap margins between gate electrode 33a and the source region 39a and between gate electrode 33a and the drain region 39b may be reduced. GIDL may be reduced while preventing a threshold voltage Vt from increasing (the on current Iₒₙ from being reduced) due to the gate fringing effect caused by the re-oxidation phenomenon of the conventional notching gate structure.

It will be apparent to those skilled in the art that various modifications and variations can be made to embodiments. Thus, it is intended that embodiments cover modifications and variations thereof within the scope of the appended claims. It is also understood that when a layer is referred to as being “on” or “over” another layer or substrate, it can be directly on the other layer or substrate, or intervening layers may also be present.

What is claimed is:

1. A device comprising:
a semiconductor substrate including source and drain regions;
a gate insulating layer formed on the semiconductor substrate;
a gate electrode formed on the gate insulating layer;
a first sidewall insulating layer formed on a side of the gate electrode;
a second sidewall insulating layer formed on a side of the first sidewall insulating layer; and
a third sidewall insulating layer formed between the first sidewall insulating layer and the second sidewall insulating layer.

2. The device of claim 1, wherein the third sidewall insulating layer is separated from the semiconductor substrate by a prescribed distance.

3. The device of claim 1, wherein a portion of the second sidewall insulating layer is provided between the first sidewall insulating layer and the semiconductor substrate.

4. The device of claim 1, wherein the separation between the third sidewall insulating layer and the semiconductor substrate comprises a gap.

5. The device of claim 1, wherein the first sidewall insulating layer and the gate insulating layer contact each other.

6. The device of claim 1, further comprising:
salicide layers formed on the gate electrode and the source and drain regions; and
etch stop layers formed on the salicide layers.

7. The device of claim 6, wherein the etch stop layers are formed on the second sidewall insulating layer.

8. A method comprising:
sequentially forming a gate insulating layer and a gate electrode on a semiconductor substrate;
forming a first sidewall insulating layer on a side of the gate electrode;
forming a second sidewall insulating layer having a notched structure on a side of the first sidewall insulating layer; and
forming a third sidewall insulating layer on a side of the second sidewall insulating layer.

9. The method of claim 8, further comprising implanting impurity ions using the third sidewall insulating layer as an ion implantation mask to form source and drain regions in the semiconductor substrate.

10. The method of claim 9, wherein the source and drain regions are formed through a high current ion implantation process and an inclination current ion implantation process.

11. The method of claim 9, further comprising forming lightly doped drain (LDD) regions in the semiconductor substrate by an ion implantation process after forming the source and drain regions.

12. The method of claim 9, further comprising forming salicide layers on the gate electrode and the source and drain regions.

13. The method of claim 8, wherein the notched structure of the second sidewall insulating layer is formed by HF cleaning.

14. The method of claim 8, wherein forming the second sidewall insulating layer comprises:
depositing at least one of a SiN layer and a tetra ethyl ortho silicate (TEOS) layer, and performing self align blanket etching; and
cleaning a bottom of the at least one SiN layer and TEOS layer using HF.

15. The method of claim 8, wherein forming the third sidewall insulating layer comprises:
depositing an insulating layer on the entire surface of the semiconductor substrate including the gate electrode through low pressure chemical vapor depositing (LPCVD); and
performing blanket etching.

16. The method of claim 8, wherein forming the gate electrode comprises:
depositing a polysilicon layer on the gate insulating layer; and
etching the polysilicon layer through a reactive ion etching (RIE) process using a high density plasma source.

17. The method of claim 15, wherein a photosensitive film for etching the polysilicon layer is patterned by at least one of an ArF and KrF lithography process with a line width of not more than 90 nm.
